(19) United States
(12) Patent Application Publication
(10) Pub. No.: US 2025/0006573 A1
(43) Pub. Date: Jan. 2, 2025

(54) OPEN CAVITY SENSOR

(71) Applicant: TEXAS INSTRUMENTS INCORPORATED, Dallas, TX (US)

(72) Inventors: Maricel Fabia ESCAÑO, Angeles City (PH); Katleen Fajardo TIMBOL, Allen, TX (US); Jeffrey Salvacion SOLAS, Iloilo City (PH)

(21) Appl. No.: 18/345,186

(22) Filed: Jun. 30, 2023

(51) Int. Cl. H01L 23/16; H01L 21/56; H01L 23/00; H01L 23/31; H01L 23/495

(52) U.S. Cl. CPC H01L 23/16; H01L 21/561; H01L 23/3157; H01L 23/495; H01L 24/48; H01L 24/85; H01L 2224/48245; H01L 2224/85

(57) ABSTRACT

In examples, a semiconductor package comprises a semiconductor die including a device side having circuitry formed therein. The device side includes a sensor. The package includes a metal member creating a hollow cavity extending through the metal member, the hollow cavity vertically aligned with the sensor, the metal member including a lower portion having a first wall thickness and an upper portion having varying wall thicknesses greater than and less than the first wall thickness, an intersection of the upper and lower portions forming a notch on an outer side of the metal member opposing the hollow cavity. The package also includes a mold compound covering portions of the semiconductor die and contacting the metal member.

### BACKGROUND

A semiconductor package may include a semiconductor die and a housing to cover the semiconductor die. The package may further include conductive terminals exposed to an exterior surface of the housing. The conductive terminals are coupled to the semiconductor die. The conductive terminals provide electrical pathways between circuitry on the semiconductor die and components (e.g., printed circuit boards) outside of the package.

### SUMMARY

In examples, a semiconductor package comprises a semiconductor die including a device side having circuitry formed therein. The device side includes a sensor. The package includes a metal member creating a hollow cavity extending through the metal member, the hollow cavity vertically aligned with the sensor, the metal member including a lower portion having a first wall thickness and an upper portion having varying wall thicknesses greater than and less than the first wall thickness, an intersection of the upper and lower portions forming a notch on an outer side of the metal member opposing the hollow cavity. The package also includes a mold compound covering portions of the semiconductor die and contacting the metal member.

In examples, a method for manufacturing a semiconductor package comprises positioning a photoresist layer on a semiconductor wafer having a sensor. The method includes using a photolithography reticle mask to alter the photoresist layer to form a first photoresist member having a first height and having a circular horizontal cross-section; a second photoresist member having a second height greater than the first height, the second photoresist member encircled by the first photoresist member and having a cylindrical shape; and a circular gap between the first and second photoresist members. The method also comprises plating a metal member having lower and upper portions, the lower portion filling the circular gap, and the upper portion extending above the circular gap such that the upper portion contacts a top surface of the first photoresist member and contacts an area of the second photoresist member that is higher than the top surface of the first photoresist member. The method also comprises removing the first and second photoresist members, the removal of the second photoresist member producing a hollow cavity in the metal member vertically aligned with the sensor.

### BRIEF DESCRIPTION OF THE DRAWINGS

FIG. 1A is a cross-sectional view of a semiconductor package having an open cavity sensor, in accordance with various examples.

FIG. 1B is a top-down view of a semiconductor package having an open cavity sensor, in accordance with various examples.

FIGS. 1C and 1D are perspective views of a semiconductor package having an open cavity sensor, in accordance with various examples.

FIG. 2 is a flow diagram of a method for manufacturing a semiconductor package having an open cavity sensor, in accordance with various examples.

FIGS. 3A-3K2 are a process flow for manufacturing a semiconductor package having an open cavity sensor, in accordance with various examples.

### DETAILED DESCRIPTION

Semiconductor packages can include various types of sensors. For example, packages may be configured to sense different properties of fluids and gases. Generally, such packages include a sensing area that is exposed to an ambient environment of the package so fluids, gases, and other materials to be sensed can come into contact with the sensing area.

Many such sensing packages are designed so the fluid, gas, or other material to be sensed does not make direct contact with porous or otherwise permeable materials, such as mold compounds, epoxies, etc. To this end, the packages may include metal walls (e.g., a cylindrical metal wall) surrounding the sensor so the material to be sensed only contacts the metal walls and the sensor, and not other, more permeable materials.

The structures of such metal walls, however, can be problematic. Many sensing packages include metal walls that have a “mushroom” shape, meaning that the top end of the wall farthest away from the package has a horizontal protrusion that obstructs access to the sensor. For instance, if the metal wall is cylindrical and the top end of the metal wall has a horizontal protrusion that obstructs the opening of the cylinder, ingress toward and egress away from the sensor becomes difficult. If ingress and egress are difficult, the flow rate of the material may be diminished, possibly resulting in inaccurate or outdated measurements by the sensor. Furthermore, photoresist may be used to form the metal wall, and if the horizontal protrusion described above obstructs the opening of the metal wall cylinder, it may be difficult to remove the photoresist during package manufacture.

This disclosure describes various examples of a semiconductor package having an open cavity sensor. The sensor is on a surface of the package and is exposed to an ambient environment of the package. The package includes a metal wall, such as a cylindrical metal wall, surrounding the sensor. Unlike prior solutions, the metal wall does not include horizontal protrusions obstructing ingress and egress of photoresist and materials to be sensed. As a result, photoresist is easily removed during manufacture, and materials to be sensed flow freely to and from the sensor, significantly improving sensor accuracy. The specific and unique semiconductor package manufacturing techniques described herein are useful to manufacture metal walls lacking horizontal protrusions that obstruct sensor access. These techniques and the resulting structures are now described with reference to the drawings.

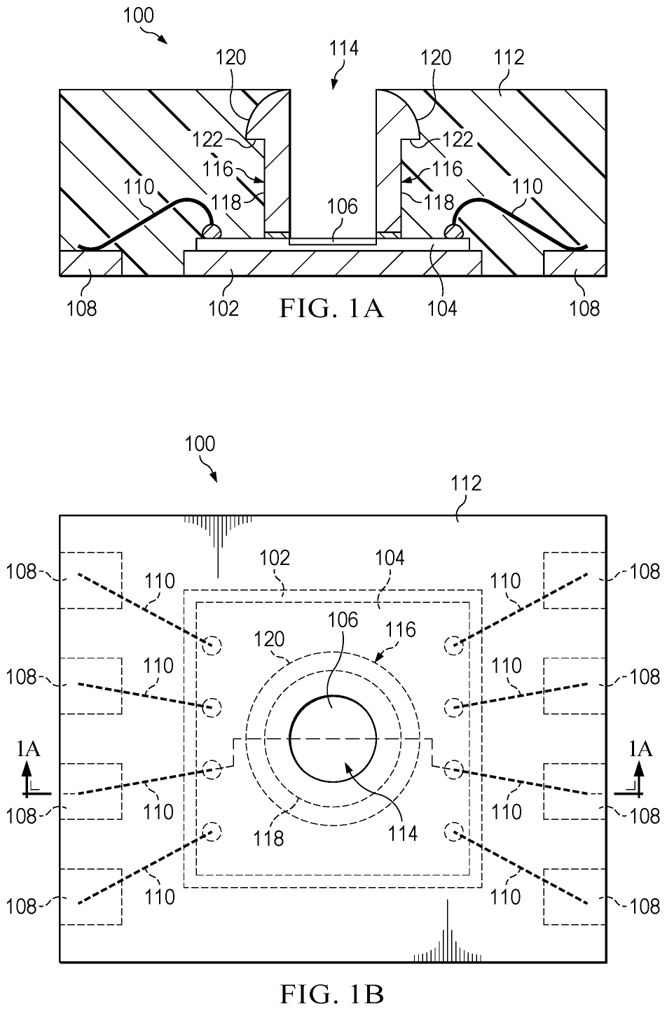

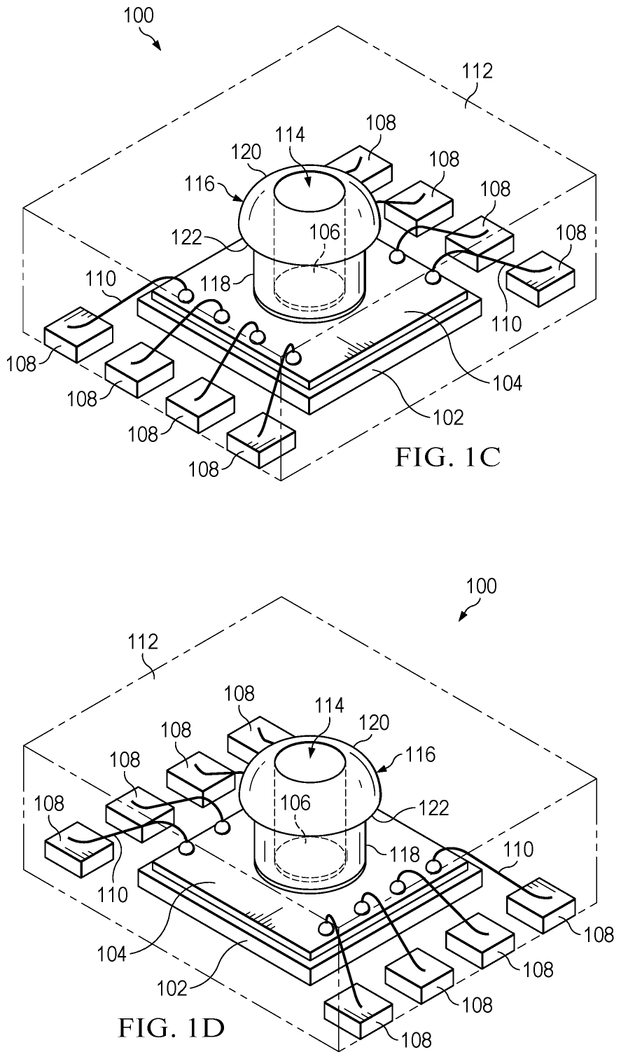

FIG. 1A is a cross-sectional view of a semiconductor package 100 having an open cavity sensor, in accordance with various examples. The package 100 is depicted as a quad flat no-lead (QFN) style package, but the techniques and structures described herein may be implemented in the context of any suitable type of package, including gullwing-style packages. The package 100 includes a die pad 102 and a semiconductor die 104 positioned on the die pad 102. The semiconductor die 104 may be coupled to the die pad 102 by way of a die attach layer, for example. The semiconductor die 104 is configured to sense one or more properties of one or more materials, such as fluids and gases. To this end, the semiconductor die 104 includes a sensor 106 formed in a top surface of the semiconductor die 104. The top surface of the semiconductor die 104 may be referred to herein as a device side of the semiconductor die 104 in which various circuitry, such as sensing circuitry (e.g., signal processing circuitry), is formed. The bottom surface of the semiconductor die 104 opposes the device side and may be referred to herein as the non-device side of the semiconductor die 104. In examples, a horizontal cross-section of the sensor 106 has a circular, ovoid, or rectangular shape. This disclosure assumes a circular shape of the sensor 106, but the scope of this disclosure is not limited as such.

The semiconductor package 100 also includes conductive terminals 108. The device side of the semiconductor die 104 is coupled to the conductive terminals 108 by way of bond wires 110. Each bond wire 110 may couple to the device side of the semiconductor die 104 by way of a ball bond and may further couple to a respective conductive terminal 108 by way of a stitch bond, for example.

In examples, a mold compound 112 covers the various components of the semiconductor package 100 that have been described above. The conductive terminals 108 are exposed to exterior surfaces of the mold compound 112 to facilitate coupling (e.g., soldering) to an exterior component or surface, such as a printed circuit board (PCB). The mold compound includes a cavity 114 (e.g., a cylindrical cavity). The cavity 114 is vertically aligned with the sensor 106, as shown. The cavity 114 has a diameter that is equivalent to the diameter of the sensor 106, assuming that the sensor 106 is circular. However, as explained, the sensor 106 may have differing shapes in different examples, and so more generally, the cavity 114 has horizontal dimensions that match or approximately match the horizontal dimensions of the sensor 106. In this way, the material to be sensed is confined to the cavity 114 and does not come into contact with (and, thus, damage) other parts of the device side of the semiconductor die 104. The cavity 114 is lined with a metal wall 116. (The cavity 114 may be said to be lined with the metal wall 116, and equivalently, the cavity 114 may be said to be formed in the metal wall 116.) The metal wall 116 may have a generally circular horizontal cross-section (as FIG. 1B depicts). The metal wall 116 includes a lower portion 118 and an upper portion 120. The lower portion 118 has a uniform thickness and a uniform inner diameter (i.e., diameter measured from wall to wall within the cavity 114), as shown. In contrast, the upper portion 120 has a uniform inner diameter (specifically due to the method of manufacture as described below), but the thickness of the upper portion 120 increases from top to bottom, as shown. At least one horizontal cross-section of the upper portion 120 has a greater thickness than the thickness of the lower portion 118, and at least one horizontal cross-section of the upper portion 120 has a smaller thickness than the thickness of the lower portion 118. In this way, the upper portion 120 has a “half-mushroom” shape. In examples, the top of the upper portion 120 is flush or approximately flush with the top surface of the mold compound 112. In examples, the top of the upper portion 120 may be exposed through (i.e., protrude through) the top surface of the mold compound 112.

The lower and upper portions 118, 120 meet at a notch 122. In some examples, the notch 122 is a right angle. The notch 122 is technically advantageous because it operates as a lock to mechanically retain mold compound 112 in place. The metal wall 116 is also technically advantageous because the metal wall 116 does not obstruct the cavity 114. Consequently, material to be sensed has free ingress and egress to and from the cavity 114 and the sensor 106.

Although the lack of horizontal protrusions obstructing the cavity 114 improves performance of the semiconductor package 100, at least some of the problems associated with such horizontal protrusions may remain if the diameter of the cavity 114 (i.e., the inner diameter of the metal wall 116) is too small. Accordingly, the diameter of the cavity 114 (i.e., the inner diameter of the metal wall 116) critically ranges from 100 microns to 150 microns, with a diameter wider than this range being disadvantageous because it would unacceptably increase die size, and with a diameter smaller than this range being disadvantageous because the diameter would not permit adequate ingress and egress of photoresist and materials to be sensed, as described above.

FIG. 1B is a top-down view of the semiconductor package 100 having an open cavity sensor, in accordance with various examples. FIGS. 1C and 1D are perspective views of the semiconductor package 100 having an open cavity sensor, in accordance with various examples.

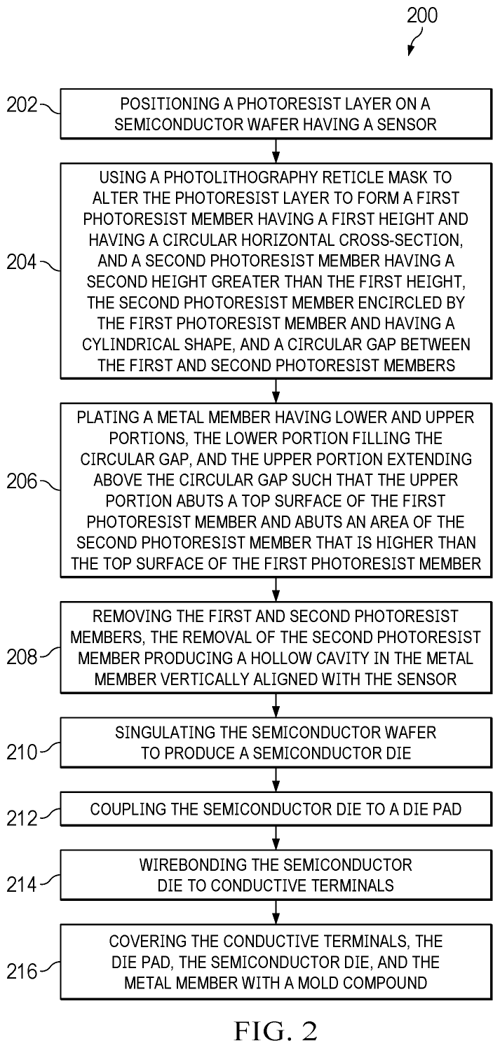

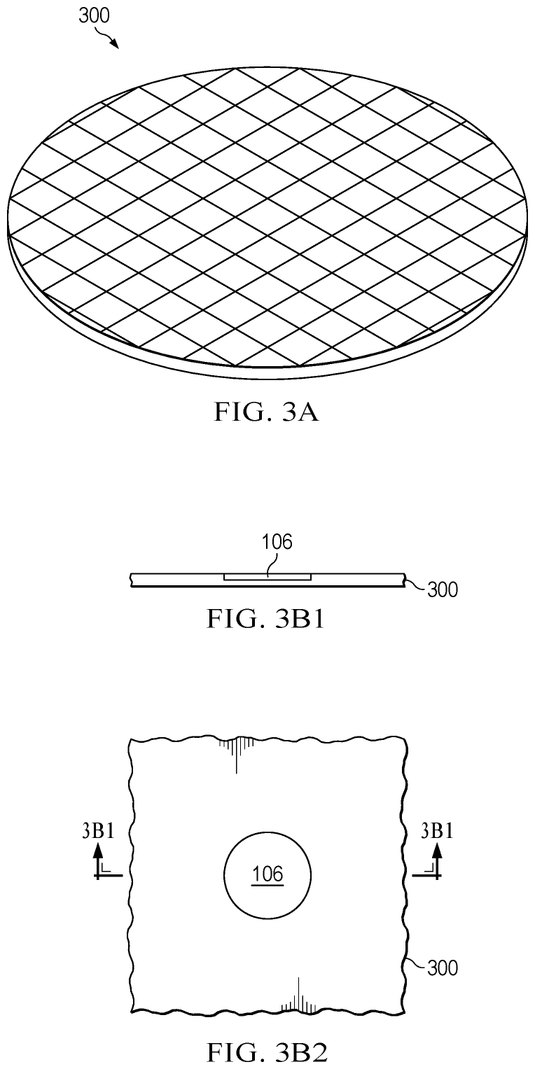

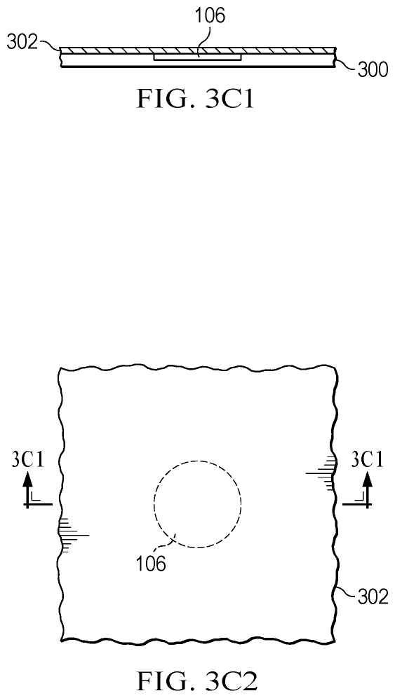

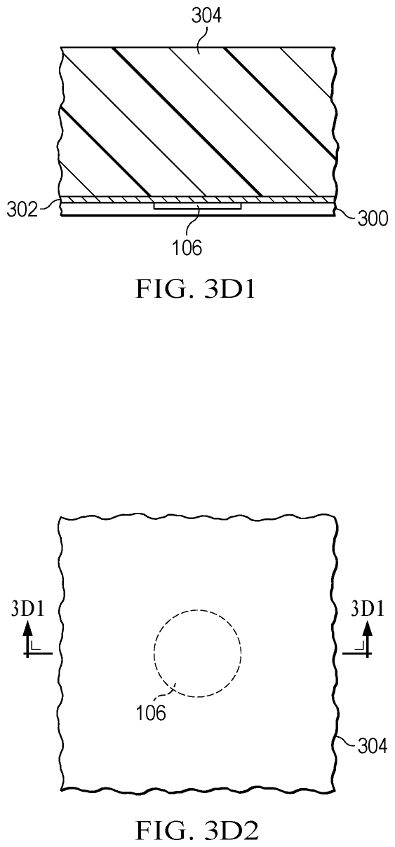

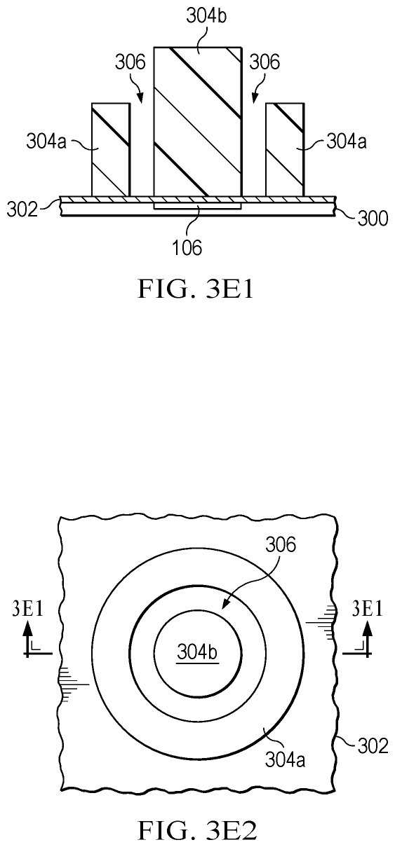

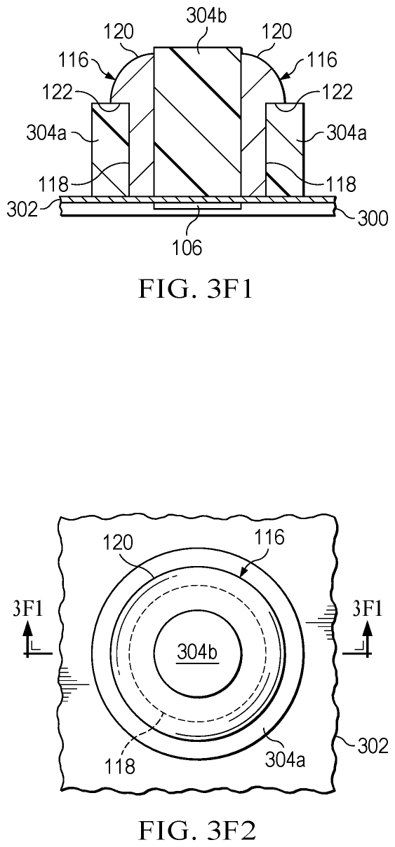

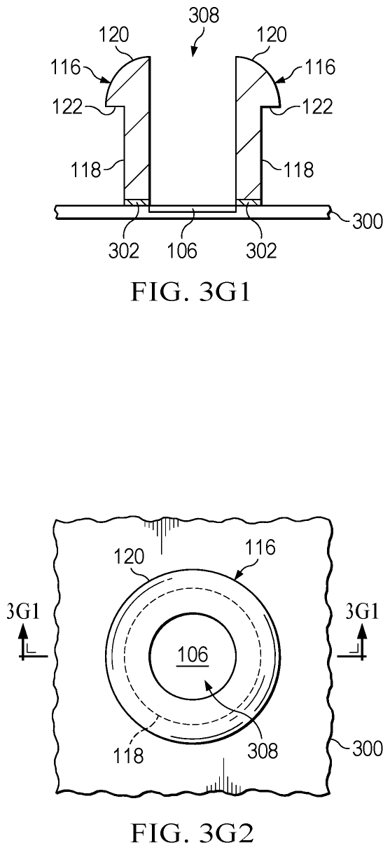

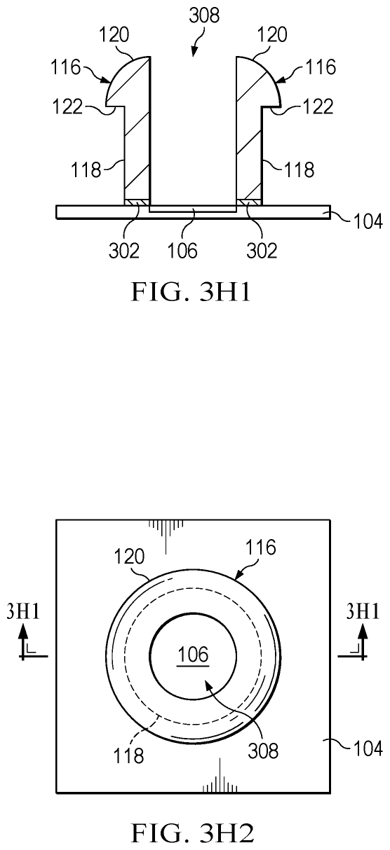

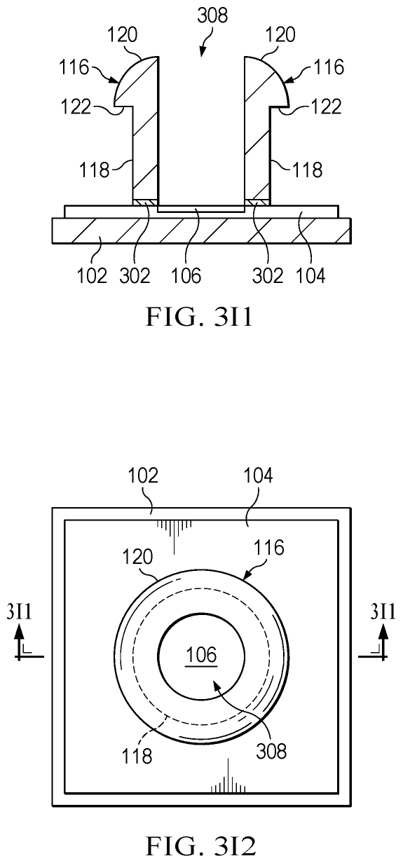

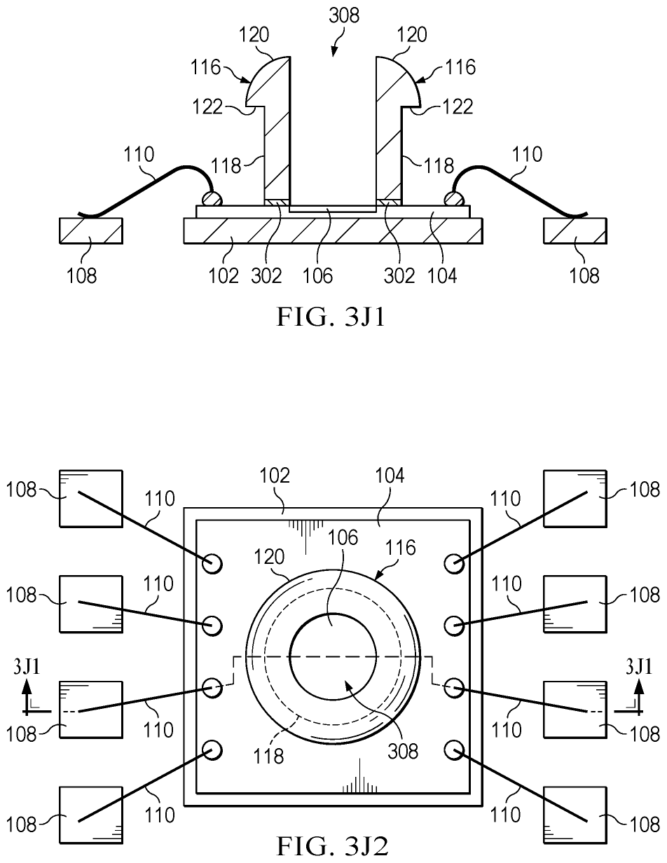

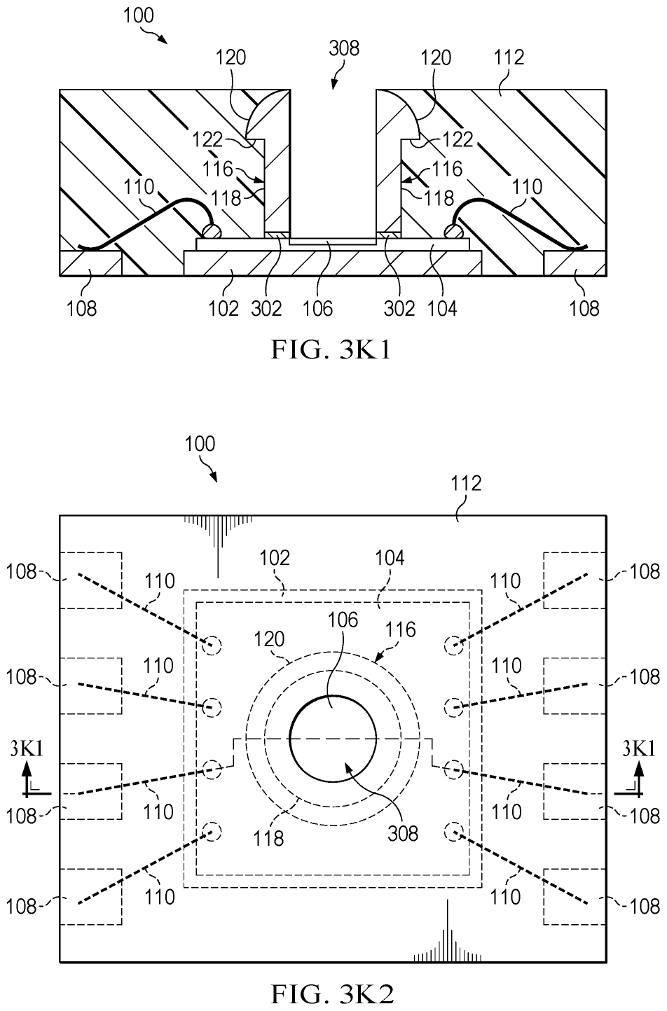

FIG. 2 is a flow diagram of a method 200 for manufacturing a semiconductor package having an open cavity sensor, such as the semiconductor package 100, in accordance with various examples. FIGS. 3A-3K2 are a process flow for manufacturing a semiconductor package having an open cavity sensor, such as the semiconductor package 100, in accordance with various examples. Accordingly, FIGS. 2 and 3A-3K2 are now described in parallel.

The method 200 includes positioning a photoresist layer on a semiconductor wafer having a sensor (202). FIG. 3A depicts a semiconductor wafer 300, such as a silicon wafer, although other semiconductor materials may be useful. FIG. 3B1 shows a profile, cross-sectional view of a portion of the wafer 300 having a sensor 106 formed on a device side of the wafer 300. The wafer 300 may include any number of sensors 106, but for ease of explanation, only one sensor 106 is shown in the process flow. FIG. 3B2 is a top-down view of the structure of FIG. 3B1.

FIG. 3C1 shows a seed layer 302 on the device side of the wafer 300. The seed layer 302 may be applied by a sputtering technique, such as a copper sputtering technique, for example. FIG. 3C2 shows a top-down view of the structure of FIG. 3C1.

FIG. 3D1 shows photoresist 304 positioned on the seed layer 302. The photoresist 304 may be a positive or a negative photoresist. Critically, the photoresist 304 must be sensitive to grayscale reticles, meaning that different amounts of light affect the photoresist 304 differently. The photoresist 304 may be applied using a spin coating technique or any other suitable technique. FIG. 3D2 is a top-down view of the structure of FIG. 3D1.

The method 200 includes using a photolithography reticle mask (i.e., a grayscale photolithography mask) to alter the photoresist layer to form a first photoresist member having a first height and having a circular horizontal cross-section, and a second photoresist member having a second height greater than the first height (204). The second photoresist member is encircled by the first photoresist member and has a cylindrical shape (204). A circular gap is between the first and second photoresist members (204). FIG. 3E1 shows the photoresist 304 having undergone a photolithography process to form photoresist members 304a and 304b. Photoresist member 304a encircles photoresist member 304b. Photoresist member 304b may be a cylinder or similar shape. A gap 306 encircles the photoresist member 304, and the photoresist member 304a encircles the gap 306. The horizontal thickness of the gap 306 determines the wall thickness of the metal wall that is later formed in the gap 306, as described below. The horizontal diameter of the photoresist member 304b determines the inner diameter of the metal wall, as described below. The photolithography process is performed accordingly on the photoresist 304, thereby forming photoresist members 304a and 304b that are sized, shaped, and positioned appropriately to achieve the target dimensions of the metal wall.

Further, the heights of the photoresist members 304a, 304b are controlled such that the photoresist member 304b is taller than photoresist member 304a. As described below, when the metal wall is plated in gap 306, the metal wall will not be formed with horizontal protrusions that obstruct the cavity within the metal wall. Differing heights may be achieved for the photoresist members 304a, 304b by using a grayscale reticle during the photolithography process, because grayscale reticles provide finer control (i.e., granularity) over the amount of light passing through the reticle and onto the photoresist 304. FIG. 3E2 is a top-down view of the structure of FIG. 3E1.

The method 200 comprises plating a metal member having lower and upper portions, the lower portion filling the circular gap, and the upper portion extending above the circular gap such that the upper portion contacts a top surface of the first photoresist member and contacts an area of the second photoresist member that is higher than the top surface of the first photoresist member (206). The structure of FIG. 3F1 is identical to the structure of FIG. 3E1, except that the metal wall 116 has been plated (e.g., electroplated) in the gap 306. Specifically, the plating fills the gap 306 and, as the plating continues vertically, some of the plated metal “spills” over onto the top surface of the photoresist member 304a to form the “half-mushroom” shape provided by the upper portion 120, as shown. The plated metal also maintains contact with the outer surface of the photoresist member 304b as plating continues. If the horizontal wall thickness of the upper portion 120 is inadequate, the notch 122 will not properly form, and thus the notch 122 will not be able to properly retain the mold compound 112, as described above. Accordingly, it is critical that the horizontal thickness of the photoresist member 304a be adequate (i.e., a minimum of 100 microns) to support the formation of an adequately thick upper portion 120 (i.e., a minimum of 40 microns horizontal thickness).

Furthermore, the difference in heights between the photoresist members 304a, 304b must be within a critical range of 60 microns to 80 microns. A smaller height difference will result in a vertically thinner upper portion 120, which may be too thin to mechanically retain the mold compound 112 and may be subject to irreparable damage. A larger height difference will result in an upper portion 120 that has excessive vertical thickness, which may result in an inadequate notch 122 for retaining the mold compound 112. FIG. 3F2 is a top-down view of the structure of FIG. 3F1.

The method 200 includes removing the first and second photoresist members, with the removal of the second photoresist member producing a hollow cavity in the metal member that is vertically aligned with the sensor (208). FIG. 3G1 shows the structure of FIG. 3F1, except with the photoresist members 304a, 304b stripped, and the hollow cavity 308 having been formed. Because no portion of the metal wall 116 obstructs the cavity 308, the photoresist member 304b is easily removed, and further, ingress and egress of sensing materials is facilitated. FIG. 3G2 is a top-down view of the structure of FIG. 3G1.

The method 200 includes singulating the semiconductor wafer to produce a semiconductor die (210). FIG. 3H1 shows the structure of FIG. 3G1, except that the wafer 300 has been singulated to produce an individual semiconductor die 104. FIG. 3H2 is a top-down view of the structure of FIG. 3H1.

The method 200 includes coupling the semiconductor die to a die pad (212) and wirebonding the semiconductor die to conductive terminals (214). FIG. 311 shows the structure of FIG. 3H1 coupled to the die pad 102. FIG. 312 is a top-down view of the structure of FIG. 311. FIG. 3J1 shows the structure of FIG. 311 having bond wires 110 coupled to the semiconductor die 104 and the conductive terminals 108. FIG. 3J2 shows a top-down view of the structure of FIG. 3J1.

The method 200 includes covering the conductive terminals, the die pad, the semiconductor die, and the metal member with a mold compound (216). FIG. 3K1 shows the structure of FIG. 3J1, but with the mold compound 112 applied to the various structures of the semiconductor package 100. A mold chase or other system for applying the mold compound 112 may be specifically designed to preclude mold compound from flowing into the cavity 308, thus leaving access to the sensor 106 unobstructed. FIG. 3K2 is a top-down view of the structure of FIG. 3K1.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die including a device side having circuitry formed therein, the device side including a sensor;
a metal member creating a hollow cavity extending through the metal member, the hollow cavity vertically aligned with the sensor, the metal member including a lower portion having a first wall thickness and an upper portion having varying wall thicknesses greater than and less than the first wall thickness, an intersection of the upper and lower portions forming a notch on an outer side of the metal member opposing the hollow cavity; and
a mold compound covering portions of the semiconductor die and contacting the metal member.

2. The package of claim 1, wherein the wall thicknesses of the upper portion decrease from a bottom of the upper portion to a top of the upper portion.

3. The package of claim 1, wherein the hollow cavity has a uniform diameter.

4. The package of claim 1, wherein the hollow cavity has a cylindrical shape.

5. The package of claim 1, wherein a diameter of the hollow cavity ranges from 100 microns to 150 microns.

6. A semiconductor package, comprising:
a semiconductor die having a sensor;
a mold compound covering the semiconductor die, the mold compound having a cavity extending through an entire thickness of the mold compound and vertically aligned with the sensor, the cavity including a lower portion having a first wall thickness and an upper portion having a second wall thickness larger than the first wall thickness; and
a metal member lining a wall of the cavity, the cavity having a uniform inner diameter,
wherein the second wall thickness tapers from a point most proximal to the semiconductor die to a point most distal to the semiconductor die.

7. The semiconductor package of claim 6, wherein a horizontal thickness of the upper portion is at least 40 microns.

8. The package of claim 7, wherein the lower and upper portions of the metal member intersect at a notch, and wherein the notch mitigates risk of the mold compound detaching from the semiconductor die.

9. The package of claim 6, wherein a diameter of the hollow cavity ranges from 100 microns to 150 microns.

10. A semiconductor package, comprising:
a semiconductor die having a sensor;
a metal member having a hollow cavity extending through the metal member and vertically aligned with the sensor, the metal member including a lower portion having a uniform wall thickness and an upper portion having opposing first and second ends, the first end closest to the lower portion and the second end farthest from the lower portion, a wall thickness of the upper portion tapering from the first end to the second end; and
a mold compound contacting an outer surface of the metal member and covering the semiconductor die.

11. The package of claim 10, wherein a diameter of the hollow cavity ranges from 100 microns to 150 microns.

12. The package of claim 11, wherein the diameter of the hollow cavity does not vary along a length of the hollow cavity.

13. The package of claim 10, further comprising conductive terminals exposed to an exterior of the mold compound and coupled to a device side of the semiconductor die on which the sensor is positioned.

14. The package of claim 10, wherein a lower surface of the upper portion extends farther away from the hollow cavity than the lower portion extends away from the hollow cavity, and wherein the lower surface of the upper portion mitigates risk of the mold compound separating from the semiconductor die.

15. The package of claim 10, wherein a horizontal thickness of the upper portion is at least 40 microns.

16. A method for manufacturing a semiconductor package, comprising:
positioning a photoresist layer on a semiconductor wafer having a sensor;
using a photolithography reticle mask to alter the photoresist layer to form:
a first photoresist member having a first height and having a circular horizontal cross-section;
a second photoresist member having a second height greater than the first height, the second photoresist member encircled by the first photoresist member and having a cylindrical shape; and
a circular gap between the first and second photoresist members;
plating a metal member having lower and upper portions, the lower portion filling the circular gap, and the upper portion extending above the circular gap such that the upper portion contacts a top surface of the first photoresist member and contacts an area of the second photoresist member that is higher than the top surface of the first photoresist member; and
removing the first and second photoresist members, the removal of the second photoresist member producing a hollow cavity in the metal member vertically aligned with the sensor.

17. The method of claim 16, further comprising:
singulating the semiconductor wafer to produce a semiconductor die;
coupling the semiconductor die to a die pad;
wirebonding the semiconductor die to conductive terminals; and
covering the conductive terminals, the die pad, the semiconductor die, and the metal member with a mold compound.

18. The method of claim 16, wherein the photoresist layer is a negative photoresist.

19. The method of claim 16, wherein the photolithography reticle mask is a grayscale reticle mask.

20. The method of claim 16, wherein the hollow cavity has a uniform diameter.

21. The method of claim 20, wherein the uniform diameter of the hollow cavity ranges from 100 microns to 150 microns.

22. A semiconductor package, comprising:
a semiconductor die including a sensor on a device side of the semiconductor die, the sensor exposed to an ambient environment of the package;
a metal wall having inner and outer surfaces, the inner surface surrounding and facing the sensor and the outer surface facing away from the sensor, the metal wall having a lower portion with a uniform wall thickness and an upper portion with varying wall thicknesses that increase from top to bottom; and
a mold compound contacting the outer surface and covering at least part of the semiconductor die.
